(19) United States
(12) Patent Application Publication
(10) Pub. No.: US 2025/0266229 A1
(43) Pub. Date: Aug. 21, 2025

(54) CIRCUIT BREAKER

(71) Applicant: TIANJIN JMT ELECTRIC CO., LTD., Tianjin (CN)

(72) Inventor: Kecheng WANG, Tianjin (CN)

(21) Appl. No.: 19/070,504

(22) Filed: Mar. 4, 2025

Related U.S. Application Data
(63) Continuation-in-part of application No. PCT/CN2024/103740, filed on Jul. 5, 2024.

(30) Foreign Application Priority Data
Jul. 14, 2023 (CN) 202321849518.3

(51) Int. Cl. H01H 71/40; H01H 71/08; H01H 71/16

(52) U.S. Cl. CPC H01H 71/402; H01H 71/08; H01H 71/16

(57) ABSTRACT

A circuit breaker including a housing, a line terminal, a load terminal, a trip device, a thermal trip mechanism, a magnetic trip mechanism, an arc extinguish chamber, a handle assembly, a one-piece line terminal lug, and a one-piece load terminal lug. The trip device includes a link assembly and a movable contact assembly. The movable contact assembly includes a movable contact; the thermal trip mechanism includes a bimetallic strip and a thermal trip hook connected to a first end of the bimetallic strip. The magnetic trip mechanism includes a moving iron core, a stationary iron core, a magnetic spring, and a firing pin. The one-piece line terminal lug includes a first bottom part and an inlet connection part and is configured to directly introduce an external power into the circuit breaker. The first bottom part is disposed at the bottom of the line terminal.

### CROSS-REFERENCE TO RELATED APPLICATIONS

This application is a continuation-in-part of International Patent Application No. PCT/CN2024/103740 with an international filing date of Jul. 5, 2024, designating the United States, now pending, further claims foreign priority benefits to Chinese Patent Application No. 202321849518.3 filed Jul. 14, 2023. The contents of all of the aforementioned applications, including any intervening amendments thereto, are incorporated herein by reference. Inquiries from the public to applicants or assignees concerning this document or the related applications should be directed to: Matthias Scholl P.C., Attn.: Dr. Matthias Scholl Esq., 245 First Street, 18th Floor, Cambridge, MA 02142.

### BACKGROUND

The disclosure relates to a circuit breaker.

The circuit breakers are common circuit protection components that disconnect the circuit in the event of short circuit, overload, or other abnormal situations, thereby protecting the circuit. Existing circuit breakers usually use soldering to connect various components, and the reliability of the solder points affects the reliability of the circuit breaker. Poor contact often occurs, so this type of circuit breaker can only be used in low current scenarios. In addition, there is a lack of directional guidance for the electric arc generated during the tripping process, which causes some arcs to overflow into the circuit breaker without entering the arc extinguish chamber. This not only damages the internal structure of the circuit breaker but also poses a fire hazard. In particular, due to the limited internal space of the circuit breaker, the tripping mechanism of the existing circuit breaker is usually single-sided tripping, and there is a couple of forces during tripping, which may result in improper tripping or damage to the tripping mechanism.

### SUMMARY

To solve the aforesaid problems, the disclosure provides a circuit breaker comprising a housing, a line terminal, a load terminal, a trip device, a thermal trip mechanism, a magnetic trip mechanism, an arc extinguish chamber, a handle assembly, a one-piece line terminal lug, and a one-piece load terminal lug.

The line terminal, the load terminal, the trip device, the thermal trip mechanism, the magnetic trip mechanism, the arc extinguish chamber, and the handle assembly are disposed in the housing.

The trip device comprises a link assembly and a movable contact assembly; the movable contact assembly comprises a movable contact; the thermal trip mechanism comprises a bimetallic strip and a thermal trip hook connected to a first end of the bimetallic strip; the magnetic trip mechanism comprises a moving iron core, a stationary iron core, a magnetic spring, and a firing pin; the one-piece line terminal lug comprises a first bottom part and an inlet connection part and is configured to directly introduce an external power into the circuit breaker; the first bottom part is disposed at a bottom of the line terminal and is directly connected to an external power line; the inlet connection part is soldered to a second end of the bimetallic strip, and a thickness of the inlet connection part is smaller than that of the first bottom part; the one-piece load terminal lug is configured to directly output the external power in the circuit breaker to an external load; the one-piece load terminal lug comprises at least a coil part, and the coil part is disposed outside the magnetic trip mechanism and is configured to trigger the magnetic trip mechanism to trip when a strong current passes through the coil part.

In a class of this embodiment, the circuit breaker further comprises a one-piece arc chute configured to guide all electric arcs generated in the circuit breaker into the arc extinguish chamber to prevent circuit hazards caused by arc overflow; the one-piece arc chute comprises an arc access part, an arc connection part, an arc guiding part, two side blocking parts, and a bottom plate; the arc access part is soldered to the second end of the bimetallic strip; the arc access part extends parallel to the bimetallic strip in one direction at an equal height; the bottom plate is disposed at a bottom of the arc extinguish chamber, and the arc guiding part is disposed between the arc access part and the bottom plate; the arc guiding part is tilted towards the arc extinguish chamber, and a projection of the static contact on the arc guiding part is close to or in a middle position of the arc guiding part; and the two side blocking parts are respectively disposed on both sides of the arc guiding part.

In a class of this embodiment, the circuit breaker further comprises two arc shields disposed outside the two side blocking parts, respectively, and the two arc shields comprise gas-generating nylon material.

In a class of this embodiment, the circuit breaker further comprises an adjustment part configured to adjust the bimetallic strip and the inlet connection part, or to adjust positions of the bimetallic strip, the inlet connection part, and the arc access part in the circuit breaker; the adjustment part comprises a connection plate and a tightening screw; the connection plate comprises a snap-in groove, a strip groove connected to the snap-in groove, and a threaded part disposed in the strip groove; the bimetallic strip and the inlet connection part are embedded in the snap-in groove, or the bimetallic strip, the inlet connection part, and the arc access part are embedded in the snap-in groove; the tightening screw is fixed on the housing, passes through the strip groove and is connected to the threaded part; by adjusting the tightening screw, positions of components embedded in the snap-in groove in the circuit breaker are adjusted.

In a class of this embodiment, the link assembly comprises a magnetic trip unit, a thermal trip unit, and a connection rod; the magnetic trip unit and the thermal trip unit are connected by interference fit, and the magnetic trip unit comprises a cross bar, a first axial hole, and a first side release; the cross bar disengages the circuit breaker when being struck by the firing pin; the thermal trip unit comprises a matching part, a thermal trip part, a second axial hole, a second side release, and a manual trip part; the matching part and the cross bar are connected by interference fit; the thermal trip part is disposed on an outer side of a connection position of the magnetic trip unit and the thermal trip unit, and when subjected to a pulling force of the thermal trip hook, the thermal trip part causes the circuit breaker to trip; the first axial hole and the second axial hole are of one size and the first axial hole and the second axial hole are coaxial; the manual trip part is connected to the handle assembly; the handle assembly operates to drive the manual trip part to trip the circuit breaker; the connection rod passes through the first axial hole, the movable contact assembly, and the second axial hole in sequence; the first side release and the second side release are interference fit, and the first side release and the second side release are coaxial, facilitating a connection between the circuit breaker and an external unit for tripping.

In a class of this embodiment, two sides of the housing are provided with trip slots; the external unit passes through the trip slots of the housing and is connected to the first side release and/or the second side release to trip the circuit breaker by the external unit.

In a class of this embodiment, the circuit breaker further comprises a current transformer; the one-piece line terminal lug further comprises a bending part passing through the current transformer; the current transformer outputs a current passing through the bending part to a load at a reciprocal of a number of coils of the current transformer.

In a class of this embodiment, the one-piece load terminal lug comprises a conductor part, a second bottom part, and a guiding part; the conductor part comprises a static contact; the second bottom part is disposed at a bottom of the load terminal, and the guiding part is disposed on one end of the conductor part adjacent to the arc extinguish chamber, for guiding an electric arc into the arc extinguish chamber.

The following advantages are associated with the circuit breaker of the disclosure.

1. The line terminal lug in the circuit breaker is an integrated design, and the external power line can be directly introduced into the circuit breaker through the terminal lug. The integrated design is more stable and reliable than solder joints.

2. The load terminal in the circuit breaker adopts an integrated design, and the load terminal integrates a coil part, making the current passing through the coil part more stable and the trip more accurate.

3. The circuit breaker comprises a one-piece arc chute and two arc shields made of gas-generating nylon material, so that the electric arc generated during tripping can be introduced into the arc extinguish chamber, avoiding safety hazards caused by arc overflow.

4. The link assembly of the circuit breaker comprises a magnetic trip unit and a thermal trip unit which are interconnected by interference fit. The link assembly is fixed to the housing through the connection rod, making the link assembly more stable during rotation and avoiding unstable release caused by the force couples. In addition, the side releases are disposed on the link assembly, and the external unit is connected to the circuit breaker through the side releases, allowing the circuit breaker to release under the command of the external unit, expanding the application scenarios of the circuit breaker.

5. The current transformer is disposed on the bending part of the one-piece line terminal lug of the circuit breaker. The current transformer converts and outputs the circuit data passing through the line terminal, and the circuit data in the circuit breaker is monitored through a backend platform. Thus, the circuit breaker is intelligent.

### BRIEF DESCRIPTION OF THE DRAWINGS

FIG. 1 is a schematic diagram of a circuit breaker according to one embodiment of the disclosure;

FIG. 2 is a schematic diagram of an internal structure of a circuit breaker according to one embodiment of the disclosure;

FIG. 3A-3B are schematic diagrams of a one-piece line terminal lug of a circuit breaker according to two embodiments of the disclosure, respectively;

FIG. 4 is a schematic diagram of a one-piece load terminal lug a circuit breaker according to one embodiment of the disclosure;

FIG. 5 is a schematic diagram of a one-piece arc chute of a circuit breaker according to one embodiment of the disclosure; and

FIG. 6 is a schematic diagram of a link assembly of a circuit breaker according to one embodiment of the disclosure.

In the drawings, the following reference numbers are used:

10. Housing; 101. Trip slot; 11. Line terminal, 12. Load terminal, 13. Handle assembly; 14. Trip device; 141. Link assembly; 1411. Magnetic trip unit; 14111. Cross bar; 14112. First axial hole; 14113. First side release; 1412. Connection rod; 1413. Thermal trip unit; 14131. Matching part; 14132. Thermal trip part; 14133. Second axial hole; 14134. Second side release; 14135. Manual trip part; 142. Movable contact assembly; 1421. Movable contact; 15. Thermal trip mechanism; 151. Bimetallic strip; 152. Thermal trip hook; 16. Magnetic trip mechanism; 161. Firing pin; 17. Arc extinguish chamber; 18. One-piece line terminal lug; 181. First bottom part; 182. Inlet connection part; 183. Bending part; 19. One-piece load terminal lug; 191. Conductor part; 1911. Static contact; 192. Coil part; 193. Second bottom part; 194. Guiding part; 20. One-piece arc chute; 201. Arc access part; 202. Arc connection part; 203. Arc guiding part; 204. Side blocking part; 205. Bottom plate; 21. Arc shield; 22. Adjustment part; 221. Connection plate; 2211. Snap-in groove; 2212. Strip groove; 2213. Threaded part; 222. Tightening screw; 23. Current transformer.

### DETAILED DESCRIPTION

To further illustrate the disclosure, embodiments detailing a circuit breaker are described below. It should be noted that the following embodiments are intended to describe and not to limit the disclosure.

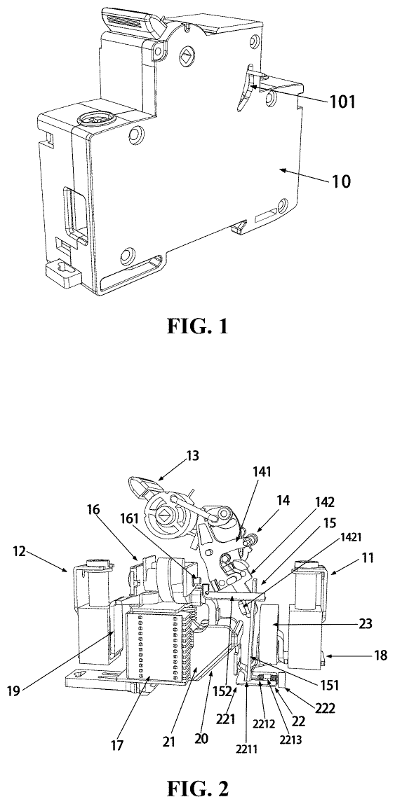

As shown in FIGS. 1 and 2, a circuit breaker comprises a housing 10, and inside the housing, there are a line terminal 11, a load terminal 12, a handle assembly 13, a trip device 14, a thermal trip mechanism 15, a magnetic trip mechanism 16, and an arc extinguish chamber 17. The trip device 14 comprises a link assembly 141 and a movable contact assembly 142; the movable contact assembly 142 comprises a movable contact 1421; the thermal trip mechanism 15 comprises a bimetallic strip 151 and a thermal trip hook 152 connected to a first end of the bimetallic strip; the magnetic trip mechanism 16 comprises a moving iron core, a stationary iron core, a magnetic spring (not shown in the drawings), and a firing pin 161.

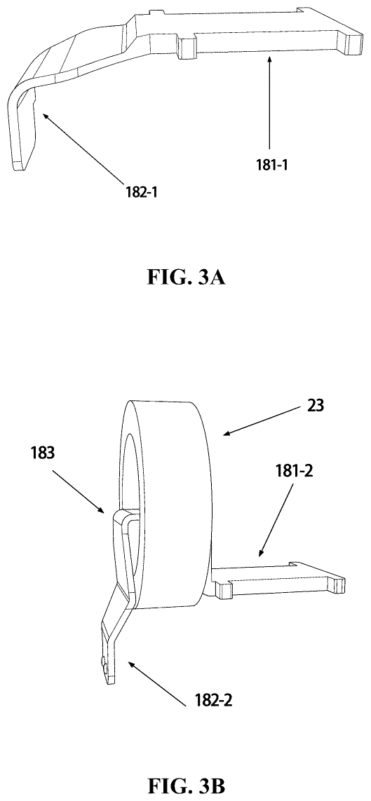

As shown in FIGS. 3A-3B, the circuit breaker further comprises a one-piece line terminal lug 18. The one-piece line terminal lug 18 comprises a first bottom part and an inlet connection part and is configured to directly introduce an external power into the circuit breaker; the first bottom part is disposed at a bottom of the line terminal and is directly connected to an external power line; the inlet connection part is soldered to a second end of the bimetallic strip, and a thickness of the inlet connection part is smaller than that of the first bottom part.

As shown in FIG. 3A, the one-piece line terminal lug 18 comprises a first bottom part 181-1 and an inlet connection part 182-1. The first bottom part 181-1 is directly connected to the external power line to conduct the current to the bimetallic strip 151 through the inlet connection part 182-1. In this embodiment, the one-piece line terminal lug 18 is designed without solder joints, with a simple structure, and is suitable for circuit breakers.

In another embodiment, as shown in FIG. 3B, the circuit breaker is an intelligent circuit breaker comprising a current transformer 23. The current transformer 23 can output the circuit data passing through it at a reciprocal of the number of coils of the current transformer 23, so that the circuit data of the circuit breaker can be monitored externally through the data of the current transformer 23. In this embodiment, the one-piece line terminal lug 18 comprises a first bottom part 181-2, an inlet connection part 182-2, and a bending part 183 passing through the current transformer 23.

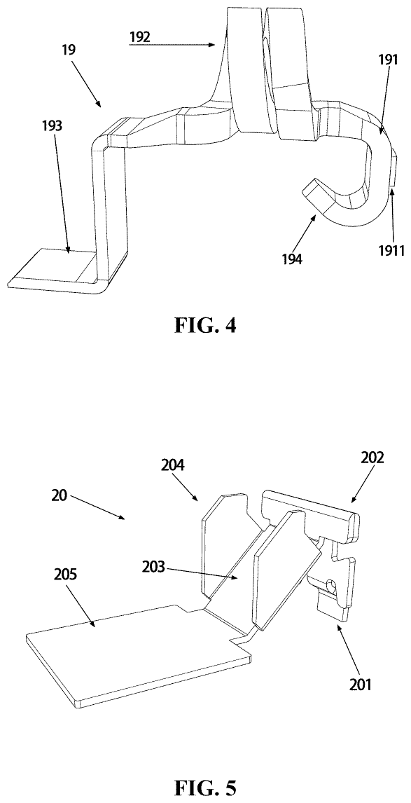

As shown in FIG. 4, the circuit breaker further comprises a one-piece load terminal lug 19 configured to directly output the external power in the circuit breaker to an external load; the one-piece load terminal lug comprises a conductor part 191, a coil part 192, a second bottom part 193, and a guiding part 194; the conductor part 191 comprises a static contact 1911; the coil part 192 is disposed outside the magnetic trip mechanism 16 and is configured to trigger the magnetic trip mechanism to trip when a strong current passes through the coil part. The second bottom part 193 is disposed at the bottom of the load terminal 12, and the guiding part 194 is disposed on one end of the conductor part 191 adjacent to the arc extinguish chamber, for guiding an electric arc into the arc extinguish chamber.

It should be noted that when the movable contact 1421 and the static contact 1911 are closed, the current enters the coil part 192 through the conductor part 191. When the movable contact 1421 and the static contact 1911 separate, the circuit is disconnected, and the electric arc generated when the movable contact 1421 and the static contact 1911 separate is guided into the arc extinguish chamber 17 through the guiding part 194.

Understandably, the magnetic trip mechanism of the circuit breaker known to personnel in this field generates a magnetic field force when the current passing through the external coil is too high; the magnetic field force pushes the moving iron core to compress the magnetic spring and causes the firing pin to strike the trip mechanism to achieve disengagement. Generally, the external coil is an independent coil that is connected to the circuit by soldering. In this embodiment, the coil part 192 is integrated on the one-piece load terminal lug 19, without soldering points, making the current entering the coil part 192 more stable. The coil part 192 replaces the external coil in traditional circuit breakers and is located outside the magnetic trip mechanism 16.

As shown in FIG. 5, the circuit breaker further comprises a one-piece arc chute 20 configured to guide all electric arcs generated in the circuit breaker into the arc extinguish chamber to prevent circuit hazards caused by arc overflow; the one-piece arc chute 20 comprises an arc access part 201, an arc connection part 202, an arc guiding part 203, two side blocking parts 204, and a bottom plate 205; the arc access part 201 is soldered to the second end of the bimetallic strip; the arc access part 201 extends parallel to the bimetallic strip in one direction at an equal height; the bottom plate 205 is disposed at a bottom of the arc extinguish chamber 17, and the arc guiding part 203 is disposed between the arc access part and the bottom plate; the arc guiding part 203 is tilted towards the arc extinguish chamber, and a projection of the static contact 1911 on the arc guiding part is close to or in a middle position of the arc guiding part 203; and the two side blocking parts 204 are respectively disposed on both sides of the arc guiding part.

Furthermore, the circuit breaker further comprises two arc shields 21 respectively disposed outside the two side blocking parts 204 to cooperate with the one-piece arc chute 20, and the two arc shields comprise gas-generating nylon material.

Furthermore, the circuit breaker further comprises an adjustment part 22 configured to adjust the bimetallic strip 151 and the inlet connection part 182, or to adjust positions of the bimetallic strip, the inlet connection part 182, and the arc access part 201 in the circuit breaker; the adjustment part 22 comprises a connection plate 221 and a tightening screw 222; the connection plate 221 comprises a snap-in groove 2211, a strip groove 2212 connected to the snap-in groove, and a threaded part 2213 disposed in the strip groove 2212; the bimetallic strip and the inlet connection part 182 are embedded in the snap-in groove 2211, or the bimetallic strip, the inlet connection part 182, and the arc access part 201 are embedded in the snap-in groove 2211; the tightening screw 222 is fixed on the housing 10, passes through the strip groove and is connected to the threaded part 2213; by adjusting the tightening screw, the positions of the components embedded in the snap-in groove in the circuit breaker are adjusted.

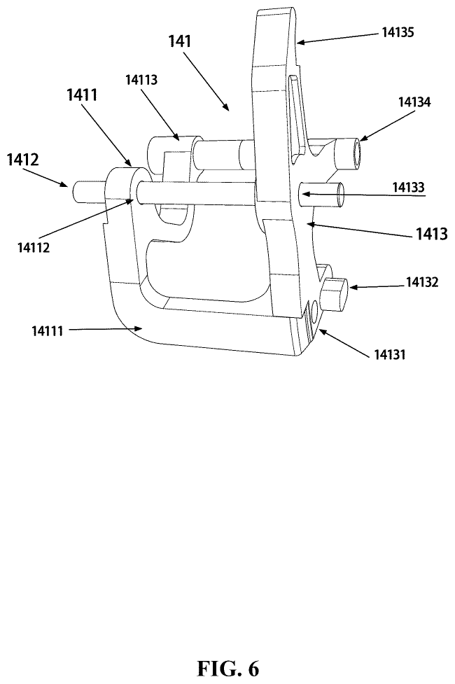

As shown in FIG. 6, the link assembly 141 comprises a magnetic trip unit 1411, a thermal trip unit 1413, and a connection rod 1412; the magnetic trip unit and the thermal trip unit are connected by interference fit, and the magnetic trip unit comprises a cross bar 14111, a first axial hole 14112, and a first side release 14113; the cross bar 14111 disengages the circuit breaker when being struck by the firing pin; the thermal trip unit 1413 comprises a matching part 14131, a thermal trip part 14132, a second axial hole 14133, a second side release 14134, and a manual trip part 14135; the matching part 14131 and the cross bar are connected by interference fit; the thermal trip part 14132 is disposed on an outer side of a connection position of the magnetic trip unit 1411 and the thermal trip unit 1413, and when subjected to a pulling force of the thermal trip hook, the thermal trip part causes the circuit breaker to trip; the first axial hole and the second axial hole are of the same size and the first axial hole and the second axial hole are coaxial; the manual trip part 14135 is connected to the handle assembly 13; the handle assembly 13 operates to drive the manual trip part 14135 to trip the circuit breaker; the connection rod 1412 passes through the first axial hole, the movable contact assembly, and the second axial hole in sequence; the first side release and the second side release are interference fit, and the first side release and the second side release are coaxial, facilitating a connection between the circuit breaker and an external unit for tripping.

Furthermore, two sides of the housing 10 are provided with trip slots 101; the external unit passes through the trip slots 101 of the housing and is connected to the first side release and/or the second side release to trip the circuit breaker by the external unit.

It will be obvious to those skilled in the art that changes and modifications may be made, and therefore, the aim in the appended claims is to cover all such changes and modifications.

What is claimed is:

1. A circuit breaker, comprising:
a housing;
a line terminal, a load terminal, a trip device, a thermal trip mechanism, a magnetic trip mechanism, an arc extinguish chamber, and a handle assembly, all of which are disposed in the housing;
a one-piece line terminal lug; and
a one-piece load terminal lug;
wherein:
the trip device comprises a link assembly and a movable contact assembly; the movable contact assembly comprises a movable contact;
the thermal trip mechanism comprises a bimetallic strip and a thermal trip hook connected to a first end of the bimetallic strip;
the magnetic trip mechanism comprises a moving iron core, a stationary iron core, a magnetic spring, and a firing pin;
the one-piece line terminal lug comprises a first bottom part and an inlet connection part and is configured to directly introduce an external power into the circuit breaker; the first bottom part is disposed at a bottom of the line terminal and is directly connected to an external power line; the inlet connection part is soldered to a second end of the bimetallic strip, and a thickness of the inlet connection part is smaller than that of the first bottom part; and
the one-piece load terminal lug is configured to directly output the external power in the circuit breaker to an external load; the one-piece load terminal lug comprises at least a coil part, and the coil part is disposed outside the magnetic trip mechanism and is configured to trigger the magnetic trip mechanism to trip when a strong current passes through the coil part.

2. The circuit breaker of claim 1, further comprising a one-piece arc chute configured to guide all electric arcs generated in the circuit breaker into the arc extinguish chamber to prevent circuit hazards caused by arc overflow; wherein the one-piece arc chute comprises an arc access part, an arc connection part, an arc guiding part, two side blocking parts, and a bottom plate; the arc access part is soldered to the second end of the bimetallic strip; the arc access part extends parallel to the bimetallic strip in one direction at an equal height; the bottom plate is disposed at a bottom of the arc extinguish chamber, and the arc guiding part is disposed between the arc access part and the bottom plate; the arc guiding part is tilted towards the arc extinguish chamber, and a projection of a static contact of the one-piece load terminal lug on the arc guiding part is close to or in a middle position of the arc guiding part; and the two side blocking parts are respectively disposed on both sides of the arc guiding part.

3. The circuit breaker of claim 2, further comprising two arc shields disposed outside the two side blocking parts, respectively, wherein the two arc shields comprise gas-generating nylon material.

4. The circuit breaker of claim 1, further comprising an adjustment part configured to adjust the bimetallic strip and the inlet connection part, or to adjust positions of the bimetallic strip, the inlet connection part, and the arc access part in the circuit breaker, wherein the adjustment part comprises a connection plate and a tightening screw; the connection plate comprises a snap-in groove, a strip groove connected to the snap-in groove, and a threaded part disposed in the strip groove; the bimetallic strip and the inlet connection part are embedded in the snap-in groove, or the bimetallic strip, the inlet connection part, and the arc access part are embedded in the snap-in groove; the tightening screw is fixed on the housing, passes through the strip groove and is connected to the threaded part.

5. The circuit breaker of claim 2, further comprising an adjustment part configured to adjust the bimetallic strip and the inlet connection part, or to adjust positions of the bimetallic strip, the inlet connection part, and the arc access part in the circuit breaker, wherein the adjustment part comprises a connection plate and a tightening screw; the connection plate comprises a snap-in groove, a strip groove connected to the snap-in groove, and a threaded part disposed in the strip groove; the bimetallic strip and the inlet connection part are embedded in the snap-in groove, or the bimetallic strip, the inlet connection part, and the arc access part are embedded in the snap-in groove; the tightening screw is fixed on the housing, passes through the strip groove and is connected to the threaded part.

6. The circuit breaker of claim 1, wherein the link assembly comprises a magnetic trip unit, a thermal trip unit, and a connection rod; the magnetic trip unit and the thermal trip unit are connected by interference fit, and the magnetic trip unit comprises a cross bar, a first axial hole, and a first side release; the cross bar disengages the circuit breaker when being struck by the firing pin; the thermal trip unit comprises a matching part, a thermal trip part, a second axial hole, a second side release, and a manual trip part; the matching part and the cross bar are connected by interference fit; the thermal trip part is disposed on an outer side of a connection position of the magnetic trip unit and the thermal trip unit, and when subjected to a pulling force of the thermal trip hook, the thermal trip part causes the circuit breaker to trip; the first axial hole and the second axial hole are of one size and the first axial hole and the second axial hole are coaxial; the manual trip part is connected to the handle assembly; the handle assembly operates to drive the manual trip part to trip the circuit breaker; the connection rod passes through the first axial hole, the movable contact assembly, and the second axial hole in sequence; the first side release and the second side release are interference fit, and the first side release and the second side release are coaxial, facilitating a connection between the circuit breaker and an external unit for tripping.

7. The circuit breaker of claim 6, wherein two sides of the housing are provided with trip slots; the external unit passes through the trip slots of the housing and is connected to the first side release and/or the second side release to trip the circuit breaker by the external unit.

8. The circuit breaker of claim 1, further comprising a current transformer, wherein the one-piece line terminal lug further comprises a bending part passing through the current transformer; the current transformer outputs a current passing through the bending part to a load at a reciprocal of a number of coils of the current transformer.

9. The circuit breaker of claim 1, wherein the one-piece load terminal lug comprises a conductor part, a second bottom part, and a guiding part; the conductor part comprises a static contact; the second bottom part is disposed at a bottom of the load terminal, and the guiding part is disposed on one end of the conductor part adjacent to the arc extinguish chamber, for guiding an electric arc into the arc extinguish chamber.
